(19) United States
(12) Patent Application Publication
(10) Pub. No.: US 2008/0099774 A1
(43) Pub. Date: May 1, 2008

(54) Method for high-volume production of light emitting diodes with attached lenses

(76) Inventors: Michael R. T. Tan, Menlo Park, CA (US); Gary R. Trott, San Mateo, CA (US)

Correspondence Address: Kathy Manke;Avago Technologies Limited, 4380 Ziegler Road, Fort Collins, CO, 80525, US

(21) Appl. No.: 11/588,501

(22) Filed: Oct. 27, 2006

(51) Int. Cl. H01L 33/00

(52) U.S. Cl. 257/98

(57) ABSTRACT

A method for high-volume production of light emitting diodes with attached lenses involves providing pre-fabricated lenses, wherein the pre-fabricated lenses are held by a common transfer structure, simultaneously attaching the pre-fabricated lenses to respective ones of light emitting diodes, and releasing the pre-fabricated lenses from the common transfer structure. In an embodiment, the light emitting diodes are distributed in a pattern on a common substrate and the common transfer structure is configured to hold the pre-fabricated lenses in a pattern that corresponds to the pattern of the light emitting diodes on the common substrate. Further, to attach the pre-fabricated lenses to the light emitting diodes, the common transfer structure is positioned relative to the common substrate such that the pre-fabricated lenses are aligned with the light emitting diodes.

### BACKGROUND OF THE INVENTION

The efficiency of light extraction from a light emitting diode (LED) is severely limited by the small critical angle to air (i.e., the angle for total internal reflection) that results from the light emitting diode's planar geometry and from the high index of refraction of the host substrate and the epitaxial layers. The index of refraction of a typical host substrate lies between 1.7 (for a GaN-based light emitting diode fabricated on a sapphire substrate) to 3.5 (for a GaAs-based light emitting diode). The high index of refraction limits the critical angle to between 36 degrees to 16 degrees, respectively. All of the light generated at angles larger than the critical angle is reflected back into the light emitting diode and either re-absorbed and recycled or re-absorbed by non-radiative centers and converted to heat. Because of the limitations imposed by the small critical angle, the extraction efficiency of a conventional light emitting diode is typically around 2% (at a critical angle of approximately 18 degrees) to around 4% (at a critical angle of approximately 27 degrees).

Many techniques that have been proposed to improve the light extraction efficiency of light emitting diodes. According to one technique, pre-fabricated lenses are attached to light emitting diodes, where the pre-fabricated lenses have a high refractive index. The attachment of the pre-fabricated lens to the light emitting diode removes the limitation of the critical angle of the light emitting diode at the interface between the light emitting diode and air, allowing more light to exit the light emitting diode thereby enhancing the extraction efficiency of the light emitting diode. Because the attached lens is pre-fabricated, fabrication of the lens does not negatively impact the light emitting diode, which permits the use of the ideal fabrication technique to produce the desired lens shapes and finishes. Although this technique works well to improve the extraction efficiency, light systems with pre-fabricated lenses attached to the light emitting diodes must be able to be economically produced.

### SUMMARY OF THE INVENTION

In accordance with an embodiment of the invention, a method for high-volume production of light emitting diodes with attached lenses involves providing pre-fabricated lenses, wherein the pre-fabricated lenses are held by a common transfer structure, simultaneously attaching the pre-fabricated lenses to respective ones of light emitting diodes, and releasing the pre-fabricated lenses from the common transfer structure. In an embodiment, the light emitting diodes are distributed in a pattern on a common substrate and the common transfer structure is configured to hold the pre-fabricated lenses in a pattern that corresponds to the pattern of the light emitting diodes on the common substrate. Further, to attach the pre-fabricated lenses to the light emitting diodes, the common transfer structure is positioned relative to the common substrate such that the pre-fabricated lenses are aligned with the light emitting diodes.

Another method for high-volume production of light emitting diodes involves holding balls comprising a material having a refractive index in the range of 1.4-2.5 by a common transfer structure, simultaneously shaping the balls into pseudo-hemispherical lenses, simultaneously attaching the pseudo-hemispherical lenses to respective ones of light emitting diodes, and releasing the pseudo-hemispherical lenses from the common transfer structure.

Other aspects and advantages of the present invention will become apparent from the following detailed description, taken in conjunction with the accompanying drawings, illustrating by way of example the principles of the invention.

### BRIEF DESCRIPTION OF THE DRAWINGS

FIG. 1 depicts a light system that includes a pre-fabricated lens attached to a light emitting diode.

FIG. 2 depicts a sapphire ball that is used to produce the pre-fabricated lens.

FIG. 3 depicts a pre-fabricated lens in the shape of a pseudo-hemisphere that is produced from the sapphire ball of FIG. 2.

FIG. 4 illustrates the attachment of the pre-fabricated lens of FIG. 3 to a light emitting diode.

FIG. 5 depicts a light emitting diode that does not include a pre-fabricated lens attached to its top surface.

FIG. 6 depicts a light emitting diode with a pre-fabricated lens attached to the top surface as described above with reference to FIGS. 1-4.

FIG. 7 depicts a side-sectional view of a common transfer structure and five sapphire balls resting within indentures of the common transfer structure.

FIG. 8 depicts an adhesive layer applied to the sapphire balls and to the common transfer structure of FIG. 7 to secure the sapphire balls to the common transfer structure.

FIG. 9 depicts pre-fabricated lenses, in the shape of pseudo-hemispheres, which are formed from the sapphire balls of FIG. 8.

FIG. 10 depicts the pre-fabricated lenses and the common transfer structure from FIG. 9 after the remaining adhesive layer is removed.

FIG. 11 depicts the pre-fabricated lenses held by the common transfer structure of FIG. 10 and a common substrate with five light emitting diodes, where the pre-fabricated lenses are aligned with the light emitting diodes.

FIG. 12 illustrates the attachment of the pre-fabricated lenses to the light emitting diodes of FIG. 11.

FIG. 13 depicts the pre-fabricated lenses attached to the light emitting diodes after the pre-fabricated lenses have been released from the common transfer structure of FIG. 12.

FIG. 14 depicts the light systems of FIG. 13 after they have been separated into individual light systems.

FIG. 15 is a process flow diagram of a method for producing light systems in accordance with an embodiment of the invention.

FIG. 16 is a process flow diagram of another method for producing light systems in accordance with an embodiment of the invention.

Throughout the description similar reference numbers may be used to identify similar elements.

### DETAILED DESCRIPTION OF THE INVENTION

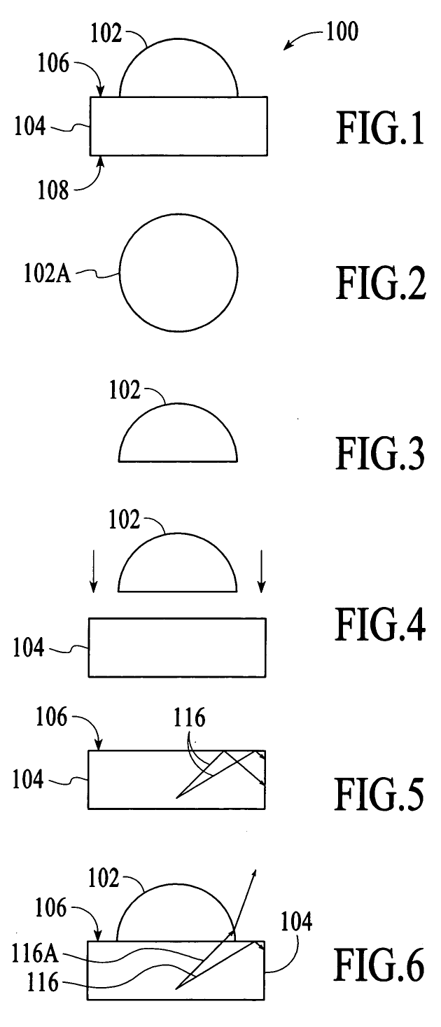

FIG. 1 depicts a light system 100 that includes a pre-fabricated lens 102 attached to a light emitting diode 104. In an embodiment, the pre-fabricated lens is attached to a planar surface of the light emitting diode through which light is emitted. In the embodiment of FIG. 1, the light emitting diode is a GaN-based light emitting diode formed on a sapphire substrate as is well-known in the field. The light emitting diode has first and second planar surfaces 106 and 108, referred to herein as “top” and “bottom” planar surfaces. In the embodiment of FIG. 1, light is emitted at least through the top major surface. While the terms “top” and “bottom” are used for description purposes, it should be understood that the first and second planar surfaces can have different orientations.

In the embodiment of FIG. 1, the pre-fabricated lens 102 is a pseudo-hemispherical dome shaped lens that is formed from a monolith of sapphire, such as a sapphire ball. In an embodiment, the pre-fabricated lens is selected to have a high refractive index, for example, in the range of 1.4-2.5. Further, the pre-fabricated lens can be selected to have a refractive index that matches the refractive index of the light emitting diode 104. In this case, the pre-fabricated lens is formed from the same material, sapphire, as the substrate material of the light emitting diode to ensure comparable refractive indices.

As depicted in FIG. 1, the pre-fabricated lens 102 is attached to the top planar surface of the light emitting diode. In one embodiment, the pre-fabricated lens is attached to the light emitting diode 104 by direct bonding. In another embodiment, the pre-fabricated lens is attached to the light emitting diode by an adhesive, such as a thin layer of an optically transparent adhesive with a thickness much less than one wavelength of the emitted light (e.g., less than one tenth of a wavelength).

A technique for producing the light system 100 of FIG. 1 is described with reference to FIGS. 2-4. FIG. 2 depicts a sapphire ball 102A that is used to produce the pre-fabricated lens 102. In an embodiment, the sapphire ball is a monolith of optical grade sapphire having a diameter in the range of 0.5-10 mm. In general, the diameter of the lens is chosen to be about 3 times the size of the LED dimension. This allows the LED to be approximated as a point source at the center of the lens.

A pre-fabricated lens is produced from the sapphire ball 102A of FIG. 2. In an embodiment, a pre-fabricated lens is produced by grinding the sapphire ball down to the desired shape. For example, the sapphire ball is ground to a pseudo-hemispherical shape. After the lens shaping is complete, the sapphire monolith is polished to form the pre-fabricated lens. FIG. 3 depicts a pre-fabricated lens 102 in the shape of a pseudo-hemisphere that is produced from the sapphire ball 102A of FIG. 2.

Once the pre-fabricated lens 102 is complete, the pre-fabricated lens is attached to a light emitting diode 104 such as a GaN-based light emitting diode formed on a sapphire substrate. FIG. 4 illustrates the attachment of the pre-fabricated lens to a light emitting diode. The pre-fabricated lens can be attached to the light emitting diode using various techniques as long as continuity is maintained between the high indices of refraction of the light emitting diode and the pre-fabricated lens. In one embodiment, the pre-fabricated lens is direct bonded to the light emitting diode and in another embodiment the pre-fabricated lens is attached to the light emitting diode by an adhesive, such as a thin layer of an optically transparent adhesive with a thickness much less than one wavelength of the emitted light (e.g., less than one-tenth of a wavelength).

By attaching a pre-fabricated lens to the light emitting diode as described above, the critical angle of the light emitting diode is eliminated at the interface between the light emitting diode and air. This enables more light to pass through the top surface of the light emitting diode and into the lens. To illustrate this point, FIG. 5 depicts a light emitting diode 104 that does not include a pre-fabricated lens 102 attached to its top surface. In the example of FIG. 5, light 116 is incident on the top surface of the light emitting diode at an angle (relative to the vertical axis) greater than the critical angle and therefore the light is totally internally reflected. Because of the small critical angle, total internal reflection greatly reduces the light extraction efficiency of the light emitting diode.

FIG. 6 depicts a light emitting diode 104 with a pre-fabricated lens 102 attached to the top surface 106 as described above with reference to FIGS. 1-4. FIG. 6 illustrates light incident on the top surface of the light emitting diode at the same angles as the light in FIG. 5, yet in contrast to FIG. 5, some of the light 116A in FIG. 6 is not totally internally reflected. In particular, FIG. 6 illustrates that light that is incident on the top surface of the light emitting diode at the interface between the pre-fabricated lens and the light emitting diode is not totally internally reflected and actually passes through the top surface of the light emitting diode into the pre-fabricated lens. From the pre-fabricated lens, the light is eventually emitted to the surrounding environment. The light that passes through the top surface of the light emitting diode and into the pre-fabricated lens is not totally internally reflected because of the shape of the lens (i.e. the rays emanating from the LED is approximately normal to the lens surface) and its matching high refractive index. FIG. 6 also illustrates that while light incident at the pre-fabricated lens interface passes through the top surface of the light emitting diode, light that is incident on the top surface of the light emitting diode outside the footprint of the pre-fabricated lens and at an angle of incidence that is greater than the critical angle of the light emitting diode is still totally internally reflected. Overall, the attached pre-fabricated lens causes more light to be extracted from the light emitting diode than in the case of a similar light emitting diode that does not include an attached pre-fabricated lens.

An advantage of the above-described technique for producing a light system is that because the lens is pre-fabricated separately from the light emitting diode, fabrication of the lens does not negatively impact the light emitting diode. The separate fabrication of the lens allows the use of any fabrication technique without consideration of how the fabrication process will impact the light emitting diode. This allows the most ideal fabrication technique to be selected to produce a lens with the desired shape and finish. For example, a lens with sag on the order of 100 um can be precisely fabricated using the best available technique without regard to how the fabrication process may impact the light emitting diode.

Although one technique for producing the pre-fabricated lens has been described, other techniques can be used to produce the pre-fabricated lens. In an example, the pre-fabricated lens can be produced using a molding and sintering process. For example, TiO₂ powder may be molded and sintered in an oxygen-rich environment to the melting point of the TiO₂ to produce a transparent glass with the desired shape at an index of refraction in the range of 2.2-2.4. Other substances like rutile, spinels, cubic zirconia and especially transparent glass ceramics can be used to yield lenses with the desired index of refraction.

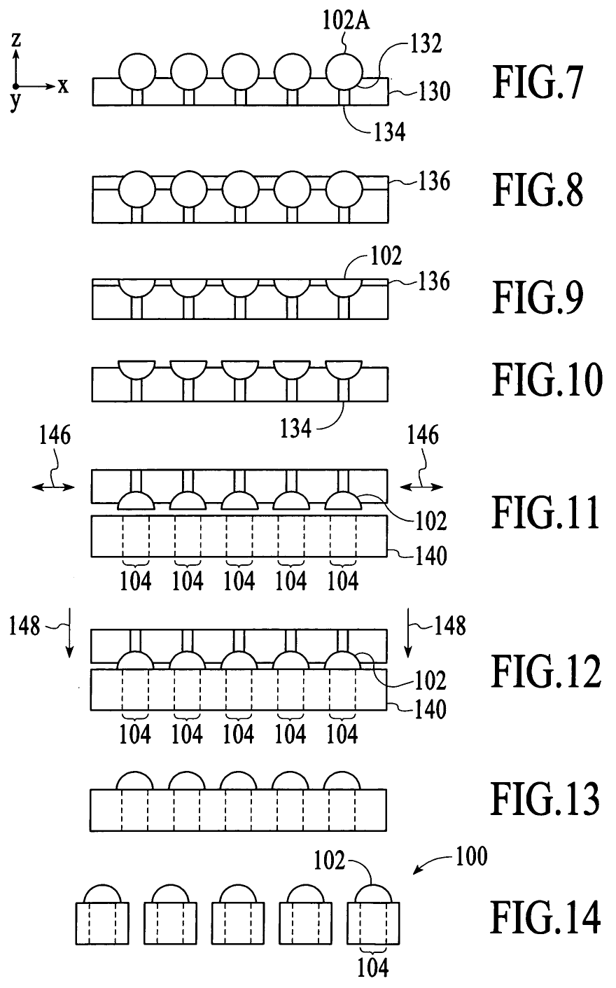

A light system with a single light emitting diode and a method for making the light system are described with reference to FIGS. 1-6. In order to produce commercially successful light systems, it is desirable to be able to efficiently produce the light systems in high volume. A high-volume technique for producing light systems similar to the light system of FIG. 1 is described with reference to FIGS. 7-14.

According to the technique, sapphire balls are initially obtained. For example, monoliths of optical grade sapphire with a high refractive index (e.g., in the range of 1.4-2.5, for example, 1.72) are obtained. The sapphire balls are then held in a common transfer structure. For example, the common transfer structure may be fabricated from a silicon wafer that includes indentures, which are smaller than the diameter of the sapphire and used to position the balls. The indentures are positioned in a pattern that corresponds to the pattern of light emitting diodes and may include small through-holes, to which a vacuum can be applied to hold the balls in place. FIG. 7 depicts a side-sectional view of a common transfer structure 130 and five sapphire balls 102A resting within indentures 132 of the common transfer structure. The common transfer structure includes a through-hole 134 at the location of each indenture that passes completely through the silicon wafer. The indentures are sized and shaped to correspond to the size and shape of the sapphire balls and the through-holes allow the sapphire balls to be held to the common transfer structure by a vacuum. The indentures can be easily fabricated by patterning and etching the silicon carrier.

Once the sapphire balls are positioned within the common transfer structure, the sapphire balls are secured into place. For example, an adhesive layer is applied to the balls and to the common transfer structure to secure the balls to the common transfer structure. FIG. 8 depicts an adhesive layer 136 applied to the sapphire balls 102A and to the common transfer structure 130 to secure the sapphire balls to the common transfer structure. In an embodiment, the adhesive layer is chosen so that it can be easily removed at a later point in the process. A suitable adhesive is, for example, a thin layer of spin coatable titanium dioxide hybrid polymer solution which has an index of 2.0 (e.g., Brewer Science A-series OptiNDEX EXP04054).

Once the sapphire balls are secured to the common transfer structure, the sapphire balls are shaped into lenses. In an embodiment, the sapphire balls are shaped into lenses by simultaneously grinding the sapphire balls to a pseudo-hemispherical shape. After the sapphire balls are ground to a pseudo-hemispherical shape, the ground surfaces are polished to form the pre-fabricated lenses. FIG. 9 depicts the pre-fabricated lenses 102, in the shape of pseudo-hemispheres, which are formed from the sapphire balls 102A (FIG. 8). As depicted in FIG. 9, the pre-fabricated lenses are shaped and polished while they are held in the common transfer structure (130).

After the grinding and polishing process, there may still be some of the adhesive layer remaining on the surface of the common transfer structure. In an embodiment, the remaining adhesive wax is removed, for example, by melting and a solvent wash. FIG. 10 depicts the pre-fabricated lenses (102) and the common transfer structure (130) after the remaining adhesive layer 136 (FIG. 9) is removed. Note that at this point, the pre-fabricated lenses are held to the common transfer structure by a vacuum which is applied via the through-holes 134.

Once the pre-fabricated lenses are completed, the common transfer structure is positioned relative to a substrate (referred to herein as a common substrate) that includes multiple light emitting diodes. In particular, the common transfer structure is positioned relative to the common substrate such that the pre-fabricated lenses are aligned with the light emitting diodes. FIG. 11 depicts the pre-fabricated lenses 102 held by the common transfer structure 130 of FIG. 10 and a common substrate 140 with five light emitting diodes 104, where the pre-fabricated lenses are aligned with the light emitting diodes. In the embodiment of FIG. 11, the pre-fabricated lenses are aligned with the light emitting diodes in the x-y plane (e.g., the horizontal plane) as indicated by arrows 146. In the embodiment of FIG. 11, the common substrate is a wafer upon which multiple light emitting diodes have been fabricated as is known in the field.

Once the pre-fabricated lenses are aligned with the light emitting diodes, the pre-fabricated lenses are attached to the light emitting diodes. FIG. 12 illustrates the attachment of the pre-fabricated lenses 102 to the light emitting diodes 104as indicated by arrows 148. In one embodiment the pre-fabricated lenses are simultaneously attached to the light emitting diodes by direct bonding while in another embodiment, the pre-fabricated lenses are simultaneously attached to the light emitting diodes by an adhesive, such as a thin layer of an optically transparent adhesive.

After the pre-fabricated lenses are attached to the light emitting diodes, the pre-fabricated lenses are released from the common transfer structure. In a system that uses a vacuum to hold the pre-fabricated lenses to the common transfer structure, the lenses are released from the common transfer structure by removing the vacuum. FIG. 13 depicts the pre-fabricated lenses 102 attached to the light emitting diodes 104 after the pre-fabricated lenses have been released from the common transfer structure 130.

In the embodiment of FIG. 13, the light emitting diodes 104 are located on a common substrate 140. In an embodiment, the light emitting diodes and corresponding pre-fabricated lens 102 are separated into individual light systems 100 using well-known wafer slicing techniques. FIG. 14 depicts the light systems of FIG. 13 after they have been separated into individual light systems.

Although GaN-based light emitting diodes are described, the above-described light systems and methods for producing the light systems are applicable to other types of light emitting diodes including, for example, AlInGaP-based light emitting diodes.

Although a common transfer structure formed from a silicon wafer is described above with reference to FIGS. 7-14, other types of common transfer structures and techniques for holding the pre-fabricated lenses are possible as long as the common transfer structure is able to hold the pre-fabricated lenses in place for alignment and attachment to the light emitting diodes. Further, although one technique for producing the pre-fabricated lenses is described, other techniques for producing the pre-fabricated lenses are possible.

Although only a side-sectional view of a single row of pre-fabricated lenses and light emitting diodes is depicted in FIGS. 7-14, the above-described technique applies as well to a two-dimensional array of pre-fabricated lenses and light emitting diodes. For example, the technique applies to a two-dimensional array or light emitting diodes that is fabricated on a circular wafer as is known in the field.

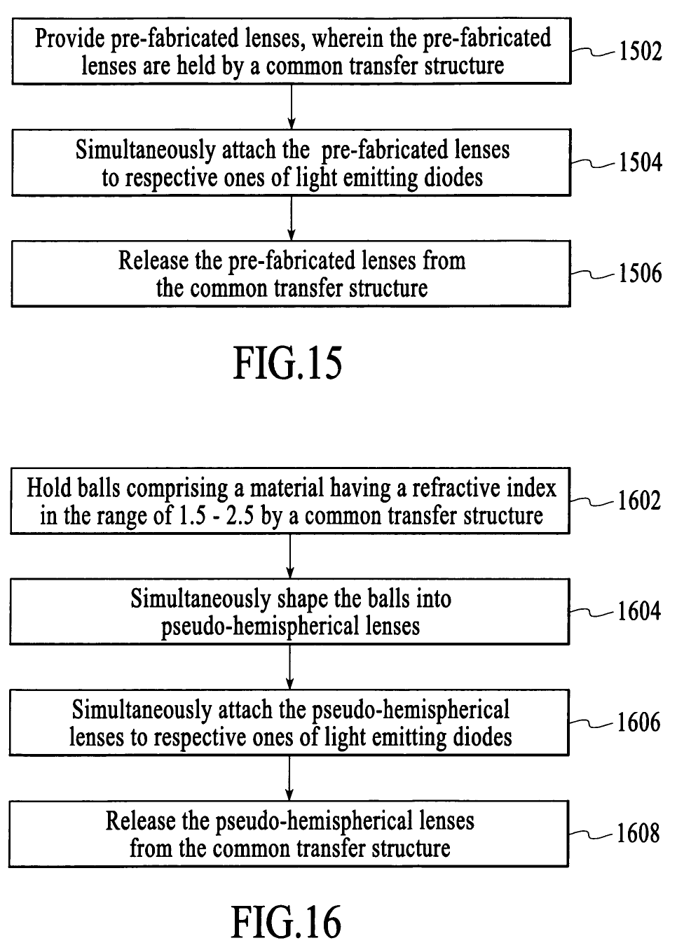

FIG. 15 is a process flow diagram of a method for producing light systems in accordance with an embodiment of the invention. At step 1502, pre-fabricated lenses are provided, wherein the pre-fabricated lenses are held by a common transfer structure. At step 1504, the pre-fabricated lenses are simultaneously attached to respective ones of light emitting diodes. At step 1506, the pre-fabricated lenses are released from the common transfer structure.

FIG. 16 is a process flow diagram of another method for producing light systems in accordance with an embodiment of the invention. At step 1602, balls comprising a material having a refractive index in the range of 1.4-2.5 are held by a common transfer structure. At step 1604, the balls are simultaneously shaped into pseudo-hemispherical lenses. At step 1606, the pseudo-hemispherical lenses are simultaneously attached to respective ones of light emitting diodes. At step 1608, the pseudo-hemispherical lenses are released from the common transfer structure.

Although specific embodiments of the invention have been described and illustrated, the invention is not to be limited to the specific forms or arrangements of parts as described and illustrated herein. The invention is limited only by the claims.

What is claimed is:

1. A method for producing light systems, the method comprising:
providing pre-fabricated lenses, wherein the pre-fabricated lenses are held by a common transfer structure;
simultaneously attaching the pre-fabricated lenses to respective ones of light emitting diodes; and
releasing the pre-fabricated lenses from the common transfer structure.

2. The method of claim 1 wherein:
the light emitting diodes are distributed in a pattern on a common substrate; and
the common transfer structure is configured to hold the pre-fabricated lenses in a pattern that corresponds to the pattern of the light emitting diodes on the common substrate.

3. The method of claim 2 wherein simultaneously attaching the pre-fabricated lenses to respective ones of the light emitting diodes comprises positioning the common transfer structure relative to the common substrate such that the pre-fabricated lenses are aligned with the light emitting diodes.

4. The method of claim 1 wherein the pre-fabricated lenses have a high refractive index.

5. The method of claim 1 wherein the pre-fabricated lenses have a refractive index in the range of 1.4-2.5.

6. The method of claim 1 wherein the light emitting diodes and pre-fabricated lenses have matching refractive indexes.

7. The method of claim 1 wherein the light emitting diodes have a planar surface and wherein the pre-fabricated lenses are attached to the planar surfaces of the light emitting diodes.

8. The method of claim 1 wherein providing the pre-fabricated lenses comprises:
providing balls; and
shaping the balls into pseudo-hemispherical lenses.

9. The method of claim 8 further comprising fixing the balls within the common transfer structure before the balls are shaped into pseudo-hemispherical lenses.

10. The method of claim 1 wherein the pre-fabricated lenses are pseudo-hemispherical in shape.

11. The method of claim 1 wherein attaching the pre-fabricated lenses to the light emitting diodes comprises direct bonding the pre-fabricated lenses to the light emitting diodes.

12. The method of claim 1 wherein attaching the pre-fabricated lenses to the light emitting diodes comprises applying an adhesive to bond the pre-fabricated lenses to the light emitting diodes.

13. A method for producing light systems, the method comprising:
holding balls comprising a material having a refractive index in the range of 1.4-2.5 by a common transfer structure;
simultaneously shaping the balls into pseudo-hemispherical lenses;
simultaneously attaching the pseudo-hemispherical lenses to respective ones of light emitting diodes; and
releasing the pseudo-hemispherical lenses from the common transfer structure.

14. The method of claim 13 wherein the light emitting diodes are GaN-based light emitting diodes formed on a sapphire substrate and wherein the balls comprise sapphire monoliths.

15. The method of claim 13 wherein simultaneously attaching the pre-fabricated lenses to respective ones of the light emitting diodes comprises positioning the common transfer structure relative to the common substrate such that the pre-fabricated lenses are aligned with the light emitting diodes.

16. A light system comprising:
light emitting diodes connected to a common substrate; and
pre-fabricated lenses attached to respective ones of the light emitting diodes.

17. The light system of claim 16 wherein the pre-fabricated lenses have a refractive index in the range of 1.4-2.5.

18. The light system of claim 16 wherein the light emitting diodes are GaN-based light emitting diodes formed on a sapphire substrate and wherein the pre-fabricated lenses are sapphire monoliths.

19. The light system of claim 16 wherein the pre-fabricated lenses are direct bonded to the light emitting diodes.

20. The light system of claim 16 wherein the pre-fabricated lenses are attached to the light emitting diodes by an adhesive.
